(19) United States
(12) Patent Application Publication
(10) Pub. No.: US 2005/0167766 A1
(43) Pub. Date: Aug. 4, 2005

(54) Semiconductor device and manufacturing method thereof

(76) Inventor: Atsushi Yagishita, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 10/874,211

(22) Filed: Jun. 24, 2004

(30) Foreign Application Priority Data
Jan. 21, 2004 (JP) 2004-013019

(51) Int. Cl. H01L 29/76

(52) U.S. Cl. 257/410

(57) ABSTRACT

A semiconductor device includes a semiconductor substrate containing silicon, a p-type semiconductor active region formed on the semiconductor substrate, a first gate insulating film containing at least one of Zr and Hf and formed on the p-type semiconductor active region, a first gate electrode formed on the first gate insulating film and formed of first silicide containing silicon and a first metal material and having a work function level lower than the central position of a band gap of the p-type semiconductor active region, and a first source region and first drain region configured by a second silicide containing silicon and the first metal material and formed to sandwich the p-type semiconductor active region.

### CROSS-REFERENCE TO RELATED APPLICATIONS

This application is based upon and claims the benefit of priority from prior Japanese Patent Application No. 2004-013019, filed Jan. 21, 2004, the entire contents of which are incorporated herein by reference.

### BACKGROUND OF THE INVENTION

1. Field of the Invention

This invention relates to a semiconductor device having Schottky source•drain regions and a manufacturing method thereof.

2. Description of the Related Art

The Schottky source•drain transistor technology which is used to form the source•drain regions of field effect transistors by using metal layers instead of impurity diffusion layers is proposed. The metal gate technology is studied to prevent the gate from being depleted and enhance the performance of the transistor.

An example of the fully-silicided metal gate technology is reported (B. Tavel et al., IEDM technical digest., pp.825-828 (2001)). In the above report, it is disclosed that the source•drain regions are formed by ion implantation and high-temperature activation heat treatment after the polysilicon gates are formed by a normal process and then the whole polysilicon gates are fully-silicided when silicide is formed on the surfaces of the source•drain regions. Further, it is reported that transistors with CoSi₂ gates and NiSi gates are manufactured as an experiment. However, the work function levels of CoSi₂ and NiSi lie near the central position of the band gap of Si and there occurs a problem that the threshold voltage of the transistor becomes high.

### BRIEF SUMMARY OF THE INVENTION

A semiconductor device according to an aspect of the invention comprises a semiconductor substrate containing silicon, a p-type semiconductor active region formed on the semiconductor substrate, a first gate insulating film containing at least one of Zr and Hf and formed on the p-type semiconductor active region, a first gate electrode formed on the first gate insulating film and formed of a first silicide containing silicon and a first metal material and having a work function level lower than the central position of a band gap of the p-type semiconductor active region, and a first source region and first drain region configured by a second silicide containing silicon and the first metal material and formed to sandwich the p-type semiconductor active region.

A manufacturing method of a semiconductor device according to another aspect of the invention comprises forming a gate insulating film containing at least one of Zr and Hf on a p-type semiconductor layer containing silicon, forming a silicon layer on the gate insulating film, patterning the silicon layer and gate insulating film, forming spacers on side walls of the patterned silicon layer, forming a first metal film on the p-type semiconductor layer and the patterned silicon layer in which the spacers are formed, performing an annealing treatment and reacting the p-type semiconductor layer with the first metal film to form source and drain regions and reacting the whole portion of the patterned silicon layer with the first metal film to form a gate electrode, and selectively removing part of the first metal film which is not reacted in the annealing treatment.

A manufacturing method of a semiconductor device according to still another aspect of the invention comprises forming a gate insulating film containing at least one of Zr and Hf on a p-type semiconductor layer containing silicon and an n-type semiconductor layer containing silicon, forming a silicon layer on the gate insulating film, patterning the silicon layer and the gate insulating film on each of the p-type semiconductor layer and the n-type semiconductor layer to form first and second patterned silicon layer respectively, forming spacers on side walls of each of the first and second patterned silicon layers, forming a first metal film on the p-type semiconductor layer and the first patterned silicon layer in which the spacers are formed, performing a first annealing treatment and reacting the p-type semiconductor layer with the first metal film to form a first source region and first drain region and reacting the first patterned silicon layer with the first metal film to form a first gate electrode, selectively removing part of the first metal film which is not reacted in the first annealing treatment, forming a second metal film on the n-type semiconductor layer and the second patterned silicon layer in which the spacers are formed, performing a second annealing treatment and reacting the n-type semiconductor layer with the second metal film to form a second source region and second drain region and reacting the second patterned silicon layer with the second metal film to form a second gate electrode, and selectively removing part of the second metal film which is not reacted in the second annealing treatment.

### BRIEF DESCRIPTION OF THE SEVERAL VIEWS OF THE DRAWING

FIG. 1 is a cross sectional view showing the configuration of a semiconductor device according to a first embodiment of this invention,

FIG. 2 is a diagram showing the possibility that silicide and SiO₂ react with each other,

FIG. 3 is a diagram showing the possibility that ErSi₂ and various types of insulating films react with each other,

FIGS. 4A to 4G are cross sectional views showing the manufacturing process of the semiconductor device according to the first embodiment,

FIGS. 5A, 5B are cross sectional views showing the manufacturing process of a semiconductor device according to a second embodiment of this invention, and

FIG. 6 is a cross sectional view showing the manufacturing process of a semiconductor device according to a third embodiment of this invention.

### DETAILED DESCRIPTION OF THE INVENTION

There will now be described embodiments of this invention with reference to the accompanying drawings.

### First Embodiment

FIG. 1 is a cross sectional view showing the configuration of a semiconductor device according to a first embodiment of this invention. As shown in FIG. 1, an n-type field effect transistor 20 and p-type field effect transistor 30 are formed. The n-type field effect transistor 20 and p-type field effect transistor 30 are formed on an SOI substrate having a buried oxide film 12 and silicon layers 23, 33 laminated on a supporting substrate 11.

First, the configuration of the n-type field effect transistor 20 is explained. A gate insulating film (first gate insulating film) 14 and first gate electrode 25 are formed on the p-type silicon layer (semiconductor layer, p-type semiconductor active region) 23. As the material of the first gate electrode 25, a material whose work function level is lower than the central position of the band gap of the silicon layers 23, 33 is used. In this embodiment, Er silicide is used.

Spacers 16 are formed on the side walls of the first gate electrode 25. First source•drain regions 27 formed of Er silicide are formed on the buried oxide film 12 to sandwich a portion lying below the first gate electrode 25. The junction between the p-type silicon layer 23 and the first source•drain region 27 is Schottky junction.

Next, the configuration of the p-type field effect transistor 30 is explained. A gate insulating film (second gate insulating film) 14 and second gate electrode 35 are formed on the n-type silicon layer 33. As the material of the second gate electrode 35, a material whose work function level is higher than the central position of the band gap of the silicon layers 23, 33 is used. In this embodiment, Pt silicide is used, for example.

Spacers 16 are formed on the side walls of the second gate electrode 35. Second source•drain regions 37 formed of Pt silicide are formed on the buried oxide film 12 to sandwich a portion lying below the second gate electrode 35. The junction between the second source•drain region 37 and the n-type silicon layer 33 is Schottky junction.

In this embodiment, since metal silicide with a low work function level is used to form the first gate electrode 25, a specified insulating film is used for the gate insulating film 14. Generally, a metal material whose work function level is low exhibits strong reactivity. Therefore, the metal material with the low work function level is easily reacted with SiO₂ which has been often used as a gate insulating film. As the result of reaction, the reliability of the gate insulating film is lowered.

The inventor of this application et al. derived a variation amount of heat of formation in the reaction between silicide and SiO₂ and thermodynamically estimated the possibility of reaction. The variation amount of heat of formation is derived as follows. First, a chemical reaction formula according to which SiO₂ reacts with MeSiₓ (CoSi₂, NiSi, PtSi, ErSi₂) to create MeO_{y} and Si is considered.
SiO₂+MeSiₓ→MeO_{y}+Si

The heat of formation on both sides of the reaction formula are calculated. A value obtained by subtracting the generated heat amount on the left side from the generated heat amount on the right side is a variation amount ΔHf (kcal/g·atom). As the variation amount is larger, the reaction becomes more difficult to occur.

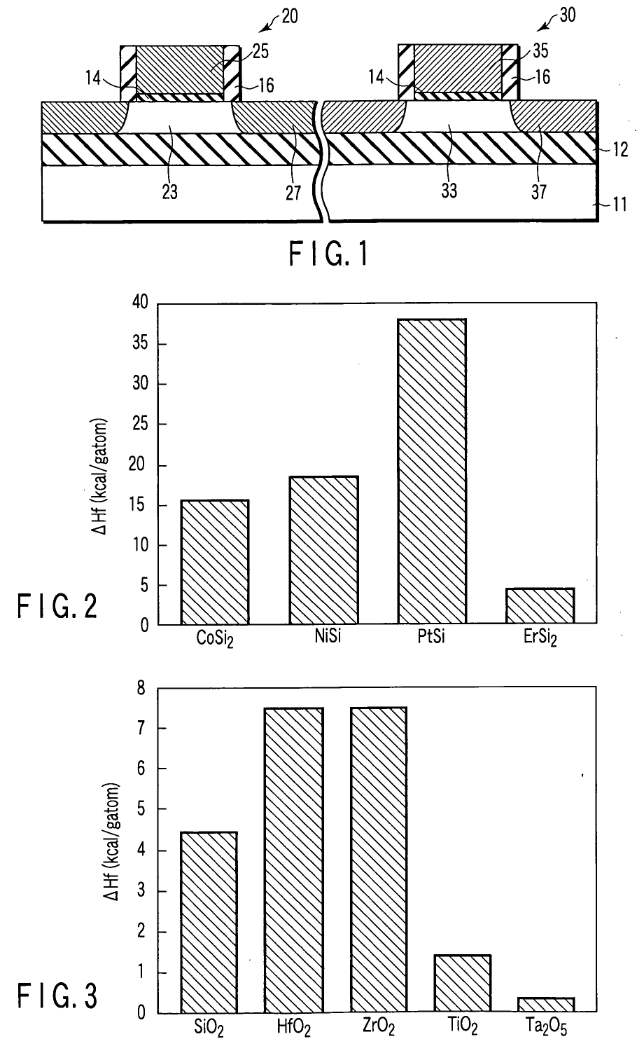

FIG. 2 shows a variation amount of heat of formation by the reaction between SiO₂ and silicide. As is clearly understood from FIG. 2, a variation amount ΔHf (heat of formation) in the case of CoSi₂, NiSi, PtSi used in the p-type MISFET is large and the reaction is difficult to occur. Therefore, when CoSi₂, NiSi, PtSi are used to form the gate electrode, no problem occurs.

On the other hand, a variation amount ΔHf in the case of ErSi₂ used as the first gate electrode 25 is small and it is understood that the reaction tends to occur. Therefore, it is difficult to use a combination of ErSi₂ and SiO₂. Thus, it is necessary to select a gate insulating film material which is difficult to react with metal silicide with low work function level.

Like silicide and SiO₂, variation amounts of heat of formation in the reactions between metal silicide (ErSi₂) and various insulating films (SiO₂, HfO₂, ZrO₂, TiO₂, Ta₂O₅) were derived. The derived result is shown in FIG. 3. As is clearly seen from FIG. 3, TiO₂, Ta₂O₅ tend to react with metal silicide ErSi₂ with low work function level and it is disadvantageous to use them. On the other hand, a high dielectric constant film of HfO₂, ZrO₂ series is thermodynamically stable and difficult to react with metal silicide ErSi₂ of low work function level in comparison with SiO₂. In the semiconductor device of the present embodiment, a high dielectric constant film of HfO₂, ZrO₂ series is used as the gate insulating film. As the high dielectric constant film of HfO₂, ZrO₂, for example, HfO₂, ZrSiO₄, ZrO₂, HfSiO₄ are provided.

As a material having a work function level lower than the central position of the band gap of Si, it is possible to use silicide of Yb, Y, Gd, Dy, Ho, La, Er. More specifically, it is possible to use YbSi₂, YSi₂, YSi, GdSi₂, DySi₂, HoSi₂, LaSi₂, LaSi, ErSi_{1.7}. A variation amount of heat of formation in the chemical reaction formula between the above material and HfO₂, ZrO₂ is approximately the same as that in the case of ErSi₂. Therefore, as the gate electrode of the n-type MISFET, it is possible to use metal silicide containing at least one metal material selected from a group consisting of Yb, Y, Gd, Dy, Ho, La and Er.

Further, as a material having a work function level higher than the central position of the band gap of Si, materials of Pd₂Si, PdSi, IrSi, IrSi₂, IrSi₃, PtSi are provided. Therefore, it is also possible to use metal silicide containing at least one metal material selected from a group consisting of Pd, Ir and Pt in order to form the gate electrode and source•drain regions of a p-type field effect transistor.

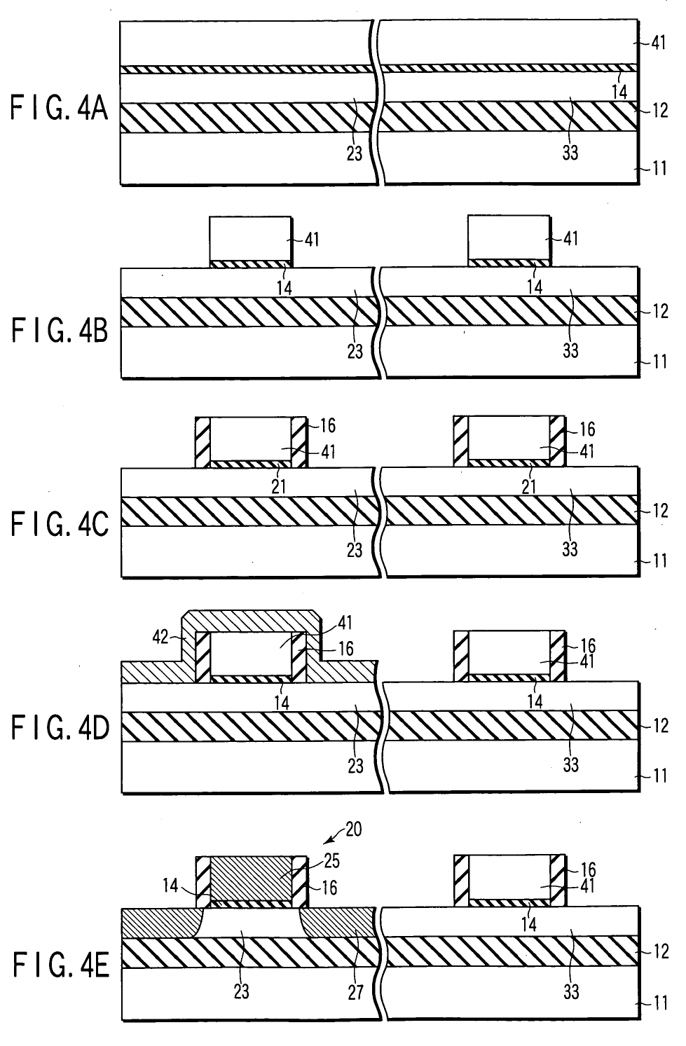

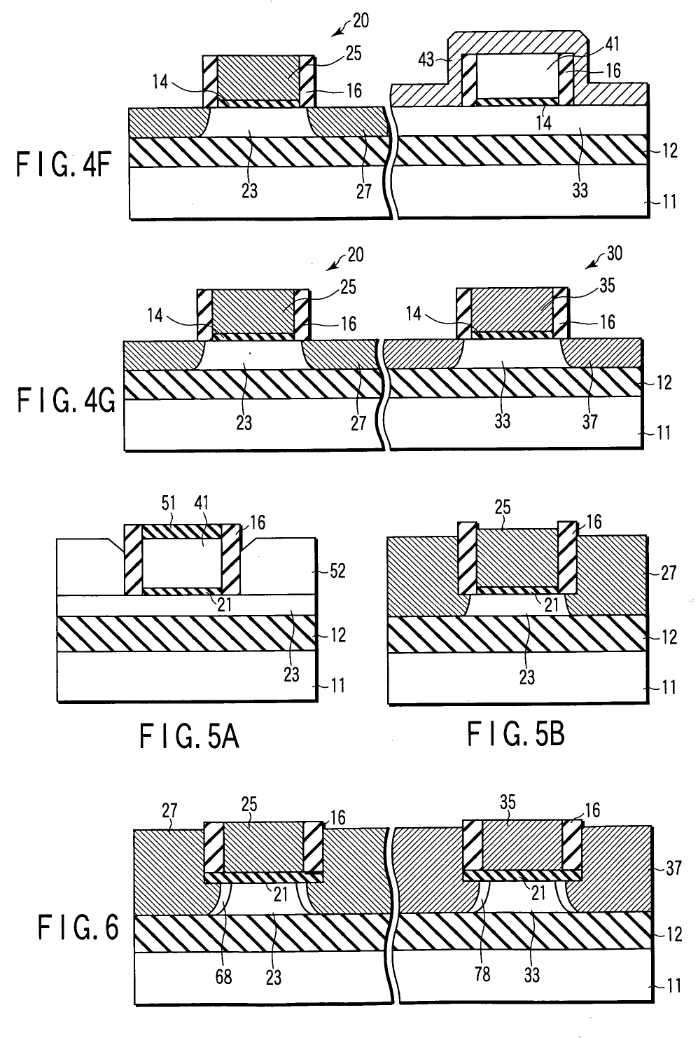

Next, the manufacturing process of the semiconductor device described above is explained with reference to FIGS. 4A to 4G. FIGS. 4A to 4G are cross sectional views showing the manufacturing process of the semiconductor device according to the first embodiment of this invention.

First, an SOI substrate having a silicon layer with a film thickness of approximately 20 nm is prepared. A device isolation (STI or mesa) structure is formed on the silicon layer of the SOI substrate by use of a normal LSI process. As shown in FIG. 4A, a p-type silicon layer 23 and n-type silicon layer 33 are formed in regions in which n-type field effect transistors and p-type silicon field effect transistors are formed, respectively. A gate insulating film (HfO₂) 14 is formed on the p-type silicon layer 23 and n-type silicon layer 33. Further, a polysilicon layer 41 is formed on the gate insulating film 14.

As shown in FIG. 4B, the polysilicon layer 41 and gate insulating film 14 are patterned into a gate electrode. Then, as shown in FIG. 4C, spacers 16 with a width of approximately 10 nm are formed on both side walls of each of the patterned polysilicon layers 41. The spacers 16 are formed by depositing an insulating film and then performing an anisotropic etching process such as an RIE process.

Next, as shown in FIG. 4D, an erbium (Er) film 42 with a film thickness of approximately 20 nm is selectively formed on the region of the n-type field effect transistors. In this process, an Er film is deposited on the entire surface, a resist film is formed on the Er film surface of the n-type field effect transistor region by use of the lithography S technology and the Er film on the p-type field effect transistor region is etched by use of a nitric acid solution. After etching, the resist film is removed.

As shown in FIG. 4E, the Er film 42 and the polysilicon film 41 and p-type polysilicon layer 23 are reacted with each other by an annealing treatment at approximately 400° C. to form first gate electrodes (Er silicide) 25 and first source•drain regions (Er silicide) 27. At this time, the device structure and process condition are optimized to fully-silicide (entirely silicify) the whole portion (from the top to the bottom) of the polysilicon layer 41 and parts of the p-type silicon layer 23 corresponding to the source•drain regions. If a non-reacted portion of the Er film 42 is left behind, the non-reacted portion of the Er film 42 is selectively etched by use of a nitric acid solution.

As shown in FIG. 4F, a platinum (Pt) film 43 with a film thickness of approximately 20 nm is selectively formed on the p-type field effect transistor region. In this process, a Pt film is deposited on the entire surface, a resist film is formed on the Pt film surface of the p-type field effect transistor region by use of the lithography technology and the Pt film on the n-type field effect transistor region is etched and removed by use of aqua regia (a mixed solution of hydrochloric acid and nitric acid). After etching, the resist film is removed.

As shown in FIG. 4G, the Pt film 43 and the polysilicon film 41 and n-type polysilicon layer 33 are reacted with each other by an annealing treatment at approximately 400° C. to form second gate electrodes (Pt silicide) 35 and second source•drain regions (Pt silicide) 37. At this time, the device structure and process condition are optimized to fully-silicide. (entirely silicify) the whole portion of the polysilicon layer 41 and parts of the n-type silicon layer 33 corresponding to the source•drain regions. If a non-reacted portion of the Pt film 43 is left behind, the non-reacted Pt film portion is selectively etched and removed by use of aqua regia after the surfaces of the Pt silicide regions 35, 37 are oxidized to a small thickness at approximately 400° C.

After this, the same manufacturing process as that of the normal LSI manufacturing process is performed. That is, an inter layer insulating film TEOS is deposited by a CVD method, contact holes are formed on the source/drain regions and gate electrodes and upper-layer metal wirings (for example, Al wirings) (not shown) are formed by a dual damascene method or the like.

In the present embodiment, the p-type field effect transistors are formed after the n-type field effect transistors are formed. However, the n-type field effect transistors may be formed after the p-type field effect transistors are formed.

According to the configuration of the present embodiment, the following effects can be attained.

If Er silicide having a work function level lower than the central position of the band gap of Si is used to form the gate electrode of the n-type field effect transistor, the threshold voltage can be lowered. Further, if Pt silicide having a work function level higher than the central position of the band gap of Si is used to form the gate electrode of the p-type field effect transistor, the threshold voltage (absolute value) can be lowered. Further, the possibility of the reaction between the gate insulating film and the gate electrode formed of Er silicide can be reduced and the reliability of the gate insulating film can be enhanced.

In addition, since the whole portion of the gate electrode and source•drain regions is formed of silicide, an ion-implantation process and high-temperature heat treatment are made unnecessary. As a result, the high dielectric constant film is difficult to be crystallized and a gate leakage current is reduced. That is, a metal gate with low threshold voltage and Schottky source•drain regions with low contact resistance can be easily and simultaneously formed by a manufacturing process with high reliability.

### Second Embodiment

A case wherein a gate polysilicon layer is formed with thickness extremely larger than the thickness of a silicon layer is considered. If a metal film with film thickness required to fully-silicide the whole portion of the polysilicon layer is deposited and subjected to the reaction for silicide, an amount of metal becomes excessive in the source•drain regions and silicide with a metal-rich composition is obtained. For example, in a case of ErSi, Er-rich silicide can be easily etched by use of nitric acid, and therefore, there occurs a possibility that silicide of the source•drain regions may be removed at the same time that non-reacted Er is removed (the selective etching process cannot be performed).

In the present embodiment, a method for solving the above problem by substantially elevating the height of the source•drain regions is explained.

The polysilicon gate and side wall spacers are patterned. As shown in FIG. 5A, a silicon oxide film 51 is formed by oxidizing the surface of the polysilicon layer 41. A single crystal silicon film 52 is formed on the surface of the exposed p-type silicon layer 23 by use of an epitaxial growth method. The upper surface of the single crystal silicon film 52 is set at substantially the same height as the upper surface of the polysilicon layer 41.

Then, the silicon oxide film 51 is selectively removed and an Er film is deposited. As shown in FIG. 5B, a gate electrode 23 and source•drain regions 27 are formed by performing an annealing process. At this time, since the total thickness of the silicon layer 23 and single crystal silicon film 52 is approximately equal to the thickness of the polysilicon layer 41, the composition of the gate electrode 25 becomes substantially the same as the composition of the source•drain regions 27. As a result, when an unnecessary metal film is selectively etched, the source•drain regions 27 are difficult to be removed.

In the case of the present embodiment, since the height of the polysilicon film is approximately the same as that of the single crystal silicon film, bridging occurs in some cases at the time of silicification. Occurrence of bridging can be prevented by polishing the surface by CMP.

According to the configuration of the present embodiment, the same effect as that of the first embodiment can be attained while formation of metal-rich silicide is avoided.

### Third Embodiment

FIG. 6 is a cross sectional view showing the manufacturing process of a semiconductor device according to a third embodiment of this invention. As shown in FIG. 6, n-type extension regions 68 are additionally formed between the p-type silicon layer 23 and the source•drain regions 27 in the configuration of the second embodiment. Further, p-type extension regions 78 are additionally formed between the n-type silicon layer 33 and the source•drain regions 37.

According to the configuration of the present embodiment, the electric field at the Schottky junction becomes strong and the resistance of the Schottky contact is reduced by the presence of the extension regions 68, 78. That is, a driving current can be increased. It is also possible to add the extension regions in the configuration of the first embodiment.

This invention is not limited to the above embodiments. For example, in the above embodiments, the SOI substrate is used, but a silicon single crystal substrate can be used. Further, as the semiconductor layer, SiGe or Ge, strained-Si, strained-SiGe, strained-Ge can be used.

Since the possibility of the reaction between the gate insulating film and the gate electrode of the p-type field effect transistor is small, it is not necessary to use a material containing Hf or Zr as the gate insulating film. However, if the insulating films of the n-type field effect transistor and p-type field effect transistor are formed of the same material, they can be simultaneously formed. Therefore, it is preferable that the insulating films of the n-type field effect transistor and p-type field effect transistor are formed of the same material from the viewpoint of the manufacturing process.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A semiconductor device comprising:
a semiconductor substrate containing silicon,
a p-type semiconductor active region formed on the semiconductor substrate,
a first gate insulating film containing at least one of Zr and Hf and formed on the p-type semiconductor active region,
a first gate electrode formed on the first gate insulating film and formed of a first silicide containing silicon and a first metal material and having a work function level lower than the central position of a band gap of the p-type semiconductor active region, and
a first source region and first drain region configured by a second silicide containing silicon and the first metal material and formed to sandwich the p-type semiconductor active region.

2. The semiconductor device according to claim 1, wherein junctions between the p-type semiconductor active region and the first source region and first drain region are Schottky junctions.

3. The semiconductor device according to claim 1, wherein the first gate insulating film is one of HfO₂, ZrSiO₄, ZrO₂, HfSiO₄.

4. The semiconductor device according to claim 1, wherein the first metal material contains at least one selected from a group consisting of Er, Yb, Y, Gd, Dy, Ho and La.

5. The semiconductor device according to claim 1, wherein the height of the upper surfaces of the first source region and first drain region is substantially elevated with respect to the height of the upper surface of the p-type semiconductor active region.

6. The semiconductor device according to claim 1, further comprising n-type extension regions respectively formed between the first source region and the p-type semiconductor active region and between the first drain region and the p-type semiconductor active region.

7. The semiconductor device according to claim 1, wherein the semiconductor substrate is an SOI substrate.

8. The semiconductor device according to claim 1, further comprising:
an n-type semiconductor active region formed on the semiconductor substrate,
a second gate insulating film formed on the n-type semiconductor active region,
a second gate electrode formed on the second gate insulating film and formed of a third silicide containing silicon and a second metal material and having a work function level higher than the central position of a band gap of the n-type semiconductor active region, and
a second source region and second drain region configured by a fourth silicide containing silicon and the second metal material and formed to sandwich the n-type semiconductor active region.

9. The semiconductor device according to claim 8, wherein junctions between the n-type semiconductor active region and the second source region and second drain region are Schottky junctions.

10. The semiconductor device according to claim 8, wherein the second gate insulating film contains at least one of Hf and Zr.

11. The semiconductor device according to claim 10, wherein the second gate insulating film is one of HfO₂, ZrSiO₄, ZrO₂, HfSiO₄.

12. The semiconductor device according to claim 8, wherein the first and second gate insulating films are formed of the same material.

13. The semiconductor device according to claim 8, wherein the second metal material contains at least one selected from a group consisting of Pt, Pd and Ir.

14. The semiconductor device according to claim 8, wherein the height of the upper surfaces of the second source region and second drain region is substantially elevated with respect to the height of the upper surface of the n-type semiconductor active region.

15. The semiconductor device according to claim 8, further comprising p-type extension regions respectively formed between the second source region and the n-type semiconductor active region and between the second drain region and the n-type semiconductor active region.

16. The semiconductor device according to claim 8, wherein the semiconductor substrate is an SOI substrate.

17. A manufacturing method of a semiconductor device comprising:
forming a gate insulating film containing at least one of Zr and Hf on a p-type semiconductor layer containing silicon,
forming a silicon layer on the gate insulating film,
patterning the silicon layer and gate insulating film,
forming spacers on side walls of the patterned silicon layer,
forming a first metal film on the p-type semiconductor layer and the patterned silicon layer in which the spacers are formed,
performing an annealing treatment and reacting the p-type semiconductor layer with the first metal film to form source and drain regions and reacting the whole portion of the patterned silicon layer with the first metal film to form a gate electrode, and
selectively removing part of the first metal film which is not reacted in the annealing treatment.

18. The manufacturing method of the semiconductor device according to claim 17, which further comprises selectively forming a silicon film on the p-type semiconductor layer after the forming the spacers and in which the first metal film is reacted with the p-type semiconductor layer and the silicon film to form the source and drain regions.

19. A manufacturing method of a semiconductor device comprising:
forming a gate insulating film containing at least one of Zr and Hf on a p-type semiconductor layer containing silicon and an n-type semiconductor layer containing silicon,
forming a silicon layer on the gate insulating film,
patterning the silicon layer and the gate insulating film on each of the p-type semiconductor layer and the n-type semiconductor layer to form first and second patterned silicon layer respectively,
forming spacers on side walls of each of the first and second patterned silicon layers,
forming a first metal film on the p-type semiconductor layer and the first patterned silicon layer in which the spacers are formed,
performing a first annealing treatment and reacting the p-type semiconductor layer with the first metal film to form a first source region and first drain region and reacting the first patterned silicon layer with the first metal film to form a first gate electrode,
selectively removing part of the first metal film which is not reacted in the first annealing treatment,
forming a second metal film on the n-type semiconductor layer and the second patterned silicon layer in which the spacers are formed,
performing a second annealing treatment and reacting the n-type semiconductor layer with the second metal film to form a second source region and second drain region and reacting the second patterned silicon layer with the second metal film to form a second gate electrode, and
selectively removing part of the second metal film which is not reacted in the second annealing treatment.

20. The manufacturing method of the semiconductor device according to claim 19, which further comprises selectively forming a silicon film on the p-type semiconductor layer and n-type semiconductor layer after the forming the spacers and in which the first metal film is reacted with the p-type semiconductor layer and the silicon film on the p-type semiconductor layer at the time of the first annealing treatment and the second metal film is reacted with the n-type semiconductor layer and the silicon film on the n-type semiconductor layer at the time of the second annealing treatment.
